(19) United States
(12) Patent Application Publication
(10) Pub. No.: US 2023/0116982 A1
(43) Pub. Date: Apr. 20, 2023

(54) ELECTRONIC DEVICE AND DEFLECTION SUPPRESSING METHOD

(71) Applicant: FUJITSU LIMITED, Kawasaki-shi (JP)

(72) Inventors: Takehisa Ishikawa, Kawasaki (JP); Satoru Noma, Hino (JP); Eiji Makabe, Kawasaki (JP)

(73) Assignee: FUJITSU LIMITED, Kawasaki-shi (JP)

(21) Appl. No.: 17/882,976

(22) Filed: Aug. 8, 2022

(30) Foreign Application Priority Data
Oct. 20, 2021 (JP) 2021-171932

(51) Int. Cl. H05K 7/14; H05K 5/02

(52) U.S. Cl. CPC H05K 7/1487; H05K 5/0208; H05K 5/0221

(57) ABSTRACT

An electronic device includes a housing that includes a bottom plate and a standing wall erected over the bottom plate, and a conversion mechanism that includes a first coupler coupled to the standing wall and a second coupler by which the first coupler is coupled to the bottom plate, and configured to convert a tensile force to act on the first coupler toward a side of the standing wall into a pulling force to act on the bottom plate from the second coupler.

### CROSS-REFERENCE TO RELATED APPLICATION

This application is based upon and claims the benefit of priority of the prior Japanese Patent Application No. 2021-171932, filed on Oct. 20, 2021, the entire contents of which are incorporated herein by reference.

### FIELD

The embodiments discussed in the present application are related to an electronic device and a deflection suppressing method.

### BACKGROUND

Some electronic devices include a housing and an internal unit housed inside the housing. In this type of electronic device, a bottom plate of the housing may deflect due to a load received from the internal unit. Therefore, the following techniques are known as techniques for suppressing deflection of the bottom plate of the housing.

For example, a technique for suppressing deflection of a bottom plate by forming a drawn portion in a bottom plate by drawing is disclosed. Furthermore, a technique for suppressing deflection of a bottom plate by connecting a first regulating member formed on a top plate of an upper case and a second regulating member formed on a bottom plate of a lower case is disclosed.

Japanese Laid-open Patent Publication No. 2008-233162 and Japanese Laid-open Patent Publication No. 2009-272579 are disclosed as related art.

### SUMMARY

According to an aspect of the embodiments, an electronic device includes a housing that includes a bottom plate and a standing wall erected over the bottom plate, and a conversion mechanism that includes a first coupler coupled to the standing wall and a second coupler by which the first coupler is coupled to the bottom plate, and configured to convert a tensile force to act on the first coupler toward a side of the standing wall into a pulling force to act on the bottom plate from the second coupler.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating an example of an information processing device;

FIG. 2 is a perspective view illustrating an electronic device of FIG. 1;

FIG. 3 is a vertical cross-sectional view illustrating an electronic device according to a first embodiment;

FIG. 4 is a perspective view illustrating a case where a lock mechanism of FIG. 3 is in a locked state;

FIG. 5 is a perspective view illustrating a case where the lock mechanism of FIG. 3 is in an unlocked state;

FIG. 6 is explanatory views illustrating an operation of a conversion mechanism of FIG. 3 in vertical cross-sectional view;

FIG. 7 is a front view illustrating a case where a lock mechanism according to a modification is in an unlocked state;

FIG. 8 is a front view illustrating a case where the lock mechanism according to the modification is in a locked state;

FIG. 9 is a vertical cross-sectional view illustrating an electronic device according to a modification;

FIG. 10 is explanatory views for describing an operation of a conversion mechanism applied to an electronic device according to a second embodiment in vertical cross-sectional view;

FIG. 11 is explanatory views for describing an operation of an interlocking mechanism of FIG. 10 in plan view;

FIG. 12 is explanatory views for describing an operation of a conversion mechanism applied to an electronic device according to a third embodiment in vertical cross-sectional view;

FIG. 13 is a perspective view illustrating an information processing device according to a first example;

FIG. 14 is a perspective view illustrating an information processing device according to a second example;

FIG. 15 is a vertical cross-sectional view illustrating an electronic device according to a first comparative example; and

FIG. 16 is a vertical cross-sectional view illustrating an electronic device according to a second comparative example.

### DESCRIPTION OF EMBODIMENTS

In the technique of forming a drawn portion in a bottom plate, mounting efficiency inside a housing deteriorates as compared with a case of absence of a drawn portion. Furthermore, in the technique of forming a columnar structure by a first regulating member formed on a top plate of an upper case and a second regulating member formed on a bottom plate of a lower case, the mounting efficiency inside the housing deteriorates as compared with a case of absence of a columnar structure.

Embodiments of a technique capable of suppressing deflection of a bottom plate while ensuring the mounting efficiency inside a housing will be described with reference to the drawings.

First, an outline of an information processing device will be described.

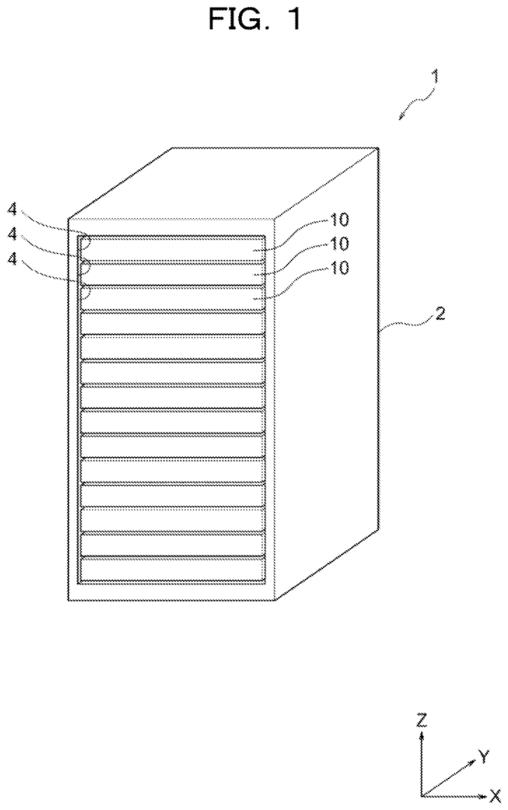

FIG. 1 illustrates an example of an information processing device. An information processing device 1 illustrated n in FIG. 1 is, for example, a server. An arrow X indicates a width direction of the information processing device 1, an arrow Y indicates a depth direction of the information processing device 1, and an arrow Z indicates a height direction of the information processing device 1. The information processing device 1 is a rack-type information processing device, and includes a rack 2 and a plurality of electronic devices 10.

The rack 2 is formed in a box shape or a frame shape. The rack 2 includes a plurality of slots 4. The plurality of slots 4 are arranged side by side in the height direction of the information processing device 1. Each of the plurality of electronic devices 10 is inserted into each slot 4.

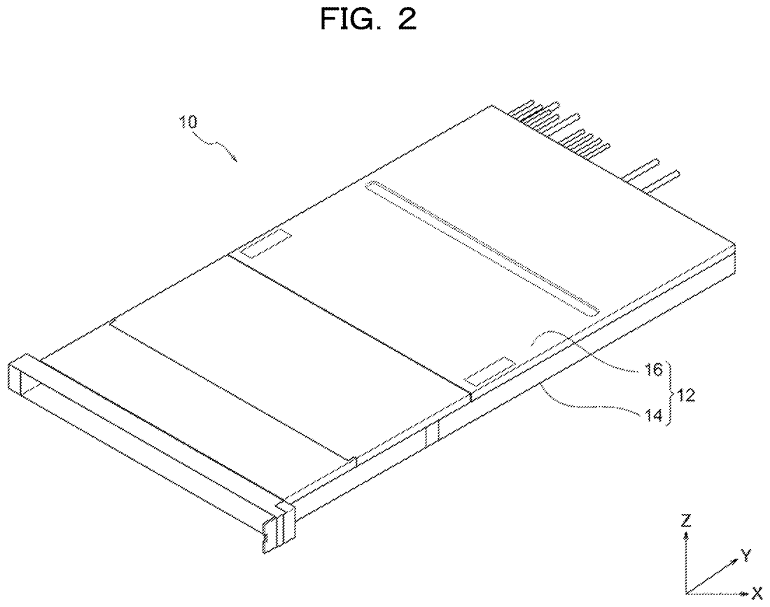

FIG. 2 illustrates an example of the electronic device 10. The electronic device 10 includes a housing 12. An internal unit (not illustrated) is housed inside the housing 12. The internal unit includes a central processing unit (CPU), a read only memory (ROM), a random access memory (RAM), a heat sink, a power supply unit, a storage, a communication circuit, and the like.

The housing 12 includes a lower housing 14 and an upper housing 16. The upper housing 16 is assembled to the lower housing 14 from an upper side of the lower housing 14. The upper housing 16 and the lower housing 14 are made of sheet metal, for example. Hereinafter, a first embodiment, a second embodiment, and a third embodiment of the electronic device 10 illustrated in FIG. 2 will be described in order.

### First Embodiment

Next, an electronic device 10 according to a first embodiment will be described.

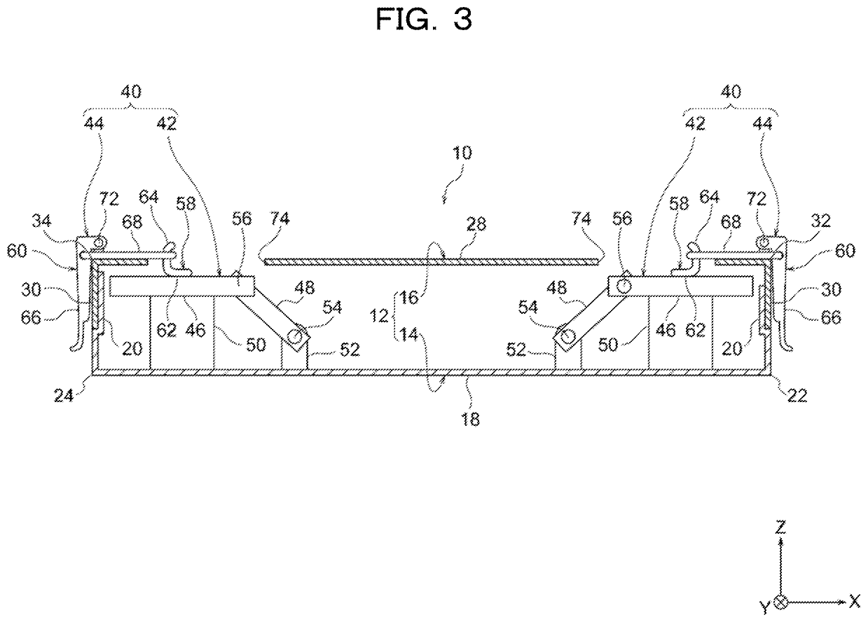

FIG. 3 illustrates the electronic device 10 according to the first embodiment. A lower housing 14 has a bottom plate 18 and a pair of standing wall portions 20. The bottom plate 18 is formed in a flat plate shape. The bottom plate 18 extends in X-Y directions. The pair of standing wall portions 20 is erected on the bottom plate 18. Each standing wall portion 20 extends in Y-Z directions. As an example, the standing wall portion 20 is a side wall portion located on a side surface of the housing 12.

One standing wall portion 20 of the pair of standing wall portions 20 is erected on a first edge portion 22 of the bottom plate 18, and the other standing wall portion 20 of the pair of standing wall portions 20 is erected on a second edge portion 24 of the bottom plate 18. The second edge portion 24 is an edge portion located on an opposite side of the first edge portion 22 in the X direction. The one standing wall portion 20 faces the other standing wall portion 20 in the X direction. The one standing wall portion 20 is an example of a “first standing wall portion”, and the other standing wall portion 20 is an example of a “second standing wall portion”.

An upper housing 16 has a top plate 28 and a pair of hanging portions 30. The top plate 28 is formed in a flat plate shape. The top plate 28 extends in the X-Y directions. In a state where the upper housing 16 is assembled to the lower housing 14, the top plate 28 faces the bottom plate 18 in the Z direction. The pair of hanging portions 30 hang down from the top plate 28. Each hanging portion 30 extends in the Y-Z directions.

One hanging portion 30 of the pair of hanging portions 30 hangs down from a first edge portion 32 of the top plate 28, and the other hanging portion 30 of the pair of hanging portions 30 hangs down from a second edge portion 34 of the top plate 28. The second edge portion 34 is an edge portion located on an opposite side of the first edge portion 32 in the X direction. The one hanging portion 30 faces the other hanging portion 30 in the X direction. Each hanging portion 30 is overlaid on an upper part of the standing wall portion 20 from an outside of the standing wall portion 20. Each hanging portion 30 is fixed to the standing wall portion 20 by, for example, screwing or the like. The standing wall portion 20 is connected to the upper housing 16 in the state where each hanging portion 30 is fixed to the standing wall portion 20.

The electronic device 10 includes a pair of conversion mechanisms 40 in addition to the above-described housing 12. As an example, the pair of conversion mechanisms 40 has a configuration symmetrical in the X direction. One conversion mechanism 40 of the pair of conversion mechanisms 40 couples the one standing wall portion 20 and the bottom plate 18, and the other conversion mechanism 40 of the pair of conversion mechanisms 40 couples the other standing wall portion 20 and the bottom plate 18. The one conversion mechanism 40 of the pair of conversion mechanisms 40 is an example of a “first conversion mechanism”, and the other conversion mechanism 40 of the pair of conversion mechanisms 40 is an example of a “second conversion mechanism”.

Each conversion mechanism 40 includes a link mechanism 42 and a lock mechanism 44. The link mechanism 42 is provided inside the housing 12. The link mechanism 42 has a first link 46 and a second link 48. The first link 46 is an example of a “first coupling portion”, and the second link 48 is an example of a “second coupling portion”. The first link 46 is located on a standing wall portion 20 side with respect to the second link 48. The first link 46 extends along the X direction. A convex support portion 50 is erected on the bottom plate 18, and the first link 46 is supported by an upper surface of the support portion 50 so as to be movable in the X direction.

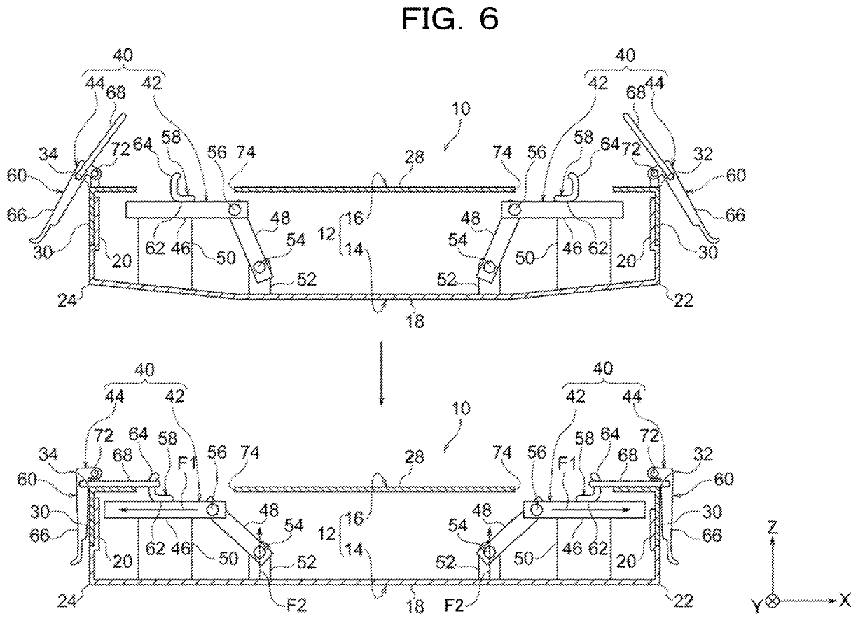

The second link 48 couples the first link 46 and the bottom plate 18. For example, a protrusion 52 protruding upward from the bottom plate 18 is formed on the bottom plate 18, and one end of the second link 48 is rotatably coupled to the protrusion 52 by a first coupling shaft 54 and the other end of the second link 48 is rotatably coupled to one end of the first link 46 by a second coupling shaft 56. The closer the coupling portion between the second link 48 and the bottom plate 18 is to a central portion of the bottom plate 18, the more the deflection suppression effect can be enhanced when a pulling force F2 (see FIG. 6) is applied to the bottom plate 18 as will be described below.

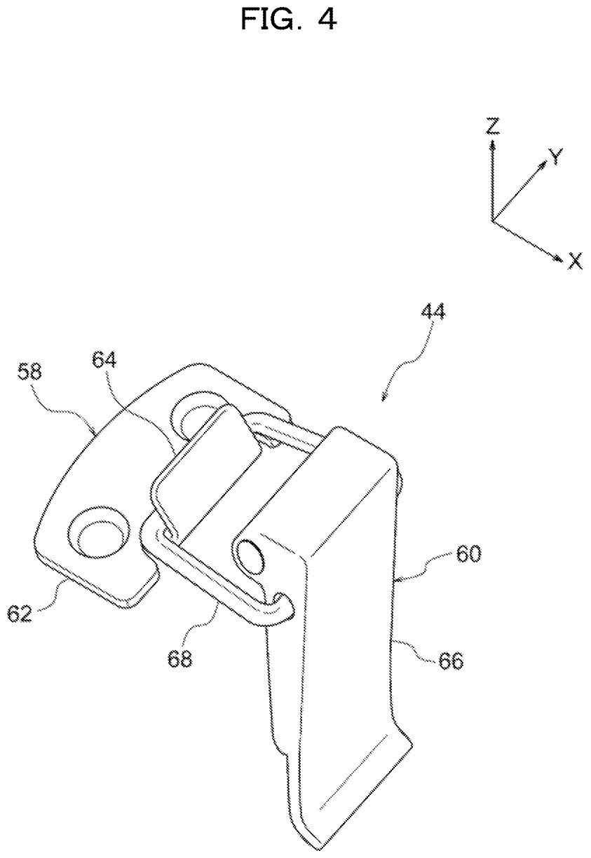

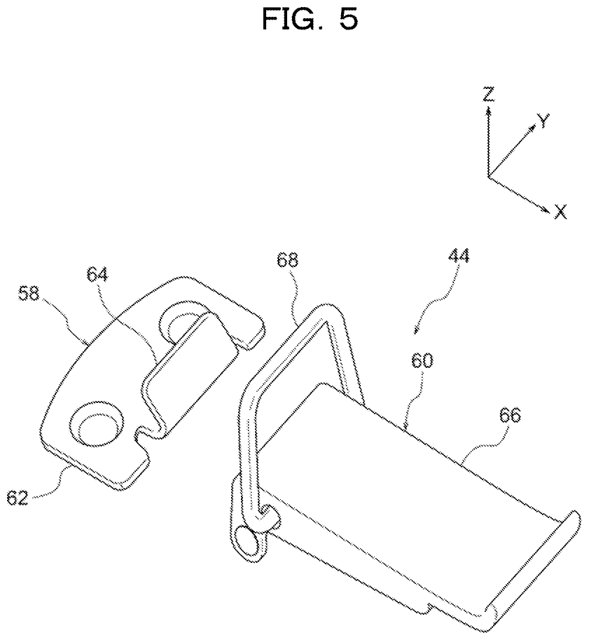

FIGS. 4 and 5 illustrate the lock mechanism 44. The lock mechanism 44 has a locked member 58 and a lever member 60. The locked member 58 is an example of a “first member”, and the lever member 60 is an example of a “second member”. As illustrated in FIG. 3, the locked member 58 is provided on an upper surface of the first link 46. The locked member 58 has a main body portion 62 and a locked portion 64. The main body portion 62 is fixed to the upper surface of the first link 46. The locked portion 64 protrudes upward from the main body portion 62.

The lever member 60 has a lever portion 66 and a locking portion 68. The lever portion 66 is rotatably supported by a corner portion on a hanging portion 30 side of the upper housing 16 via a coupling shaft 72. The lever portion 66 is fixed to the standing wall portion 20 via the upper housing 16 in the state where the upper housing 16 is assembled to the lower housing 14. The lever portion 66 rotates upward when a force is applied to an upper side by an operator, and rotates downward when a force is applied to a lower side by the operator. The locking portion 68 is formed in a frame shape. The locking portion 68 is rotatably supported by the lever portion 66. An opening 74 is formed in the top plate 28. The locked portion 64 is movably inserted into the opening 74. The opening 74 is formed over a range in which the locked portion 64 moves.

The lock mechanism 44 may take an unlocked state and a locked state. FIGS. 3 and 4 illustrate the locked state of the lock mechanism 44, and FIG. 5 illustrates the unlocked state of the lock mechanism 44. Furthermore, FIG. 6 illustrates how the lock mechanism 44 transitions from the unlocked state to the locked state.

The unlocked state is a state in which the locking portion 68 is separated from the locked portion 64, and the locked member 58 and the lever member 60 are separated, when the lever portion 66 rotates upward. In the unlocked state, the locked member 58 and the lever member 60 are separated, so that the first link 46 is allowed to move with respect to the standing wall portion 20.

In the locked state, the locked member 58 and the lever member 60 are in the coupled state when the lever portion 66 rotates downward in the state where the locking portion 68 is locked with the locked portion 64 (for example, in a hooked state). A spring (not illustrated) is provided between the lever portion 66 and the coupling shaft 72, and the lever portion 66 is held in a state of being rotated downward by an urging force of the spring in the state where the lever portion 66 is rotated downward. In the locked state, the first link 46 is fixed to the standing wall portion 20 in a state where the first link 46 is pulled toward the standing wall portion 20 side.

As illustrated in FIG. 6, in the conversion mechanism 40, when the lock mechanism 44 transitions from the unlocked state to the locked state, the first link 46 is pulled toward the standing wall portion 20 side as the lever portion 66 rotates downward. When the first link 46 is pulled toward the standing wall portion 20 side, a tensile force Ft acts on the first link 46 toward the standing wall portion 20 side. When the tensile force F1 acts on the first link 46 toward the standing wall portion 20 side, the tensile force F1 is transmitted to the second link 48, and the upward pulling force F2 acts on the bottom plate 18 from the second link 48. For example, the conversion mechanism 40 has a function to convert the tensile force F1 acting on the first link 46 toward the standing wall portion 20 side into the pulling force F2 acting upward on the bottom plate 18 from the second link 48. The conversion mechanism 40 described above may be selectively provided at a position in the housing 12 where deflection is likely to occur due to a load from the internal unit.

Next, a method of using the conversion mechanism 40 according to the first embodiment will be described.

In the method of using the conversion mechanism 40 according to the first embodiment, first, the upper housing 16 is assembled to the lower housing 14. Next, a force is applied to the lower side of the lever portion 66 in the state where the locking portion 68 is hooked on the locked portion 64, so that the lever portion 66 rotates downward. When the lever portion 66 rotates downward, the first link 46 is pulled toward the standing wall portion 20 side.

When the first link 46 is pulled toward the standing wall portion 20 side, a tensile force F1 acts on the first link 46 toward the standing wall portion 20 side. When the tensile force F1 acts on the first link 46 toward the standing wall portion 20 side, the tensile force F1 is transmitted to the second link 48, and the upward pulling force F2 acts on the bottom plate 18 from the second link 48.

Then, the tensile force F1 acting on the first link 46 toward the standing wall portion 20 side is converted by the conversion mechanism 40 into the pulling force F2 acting upward on the bottom plate 18 from the second link 48, whereby the deflection of the bottom plate 18 is suppressed. The method of using the conversion mechanism 40 is an example of a “deflection suppressing method”.

Next, operation and effect of the first embodiment will be described.

The weight of the internal unit housed inside the housing 12 has increased due to the recent high-density mounting. Therefore, the bottom plate 18 of the housing 12 may deflect downward due to the load received from the internal unit. Furthermore, as the bottom plate 18 deflects downward, the top plate 28 may also deflect downward in a similar manner to the bottom plate 18. For example, the electronic device 10 may deflect downward as a whole.

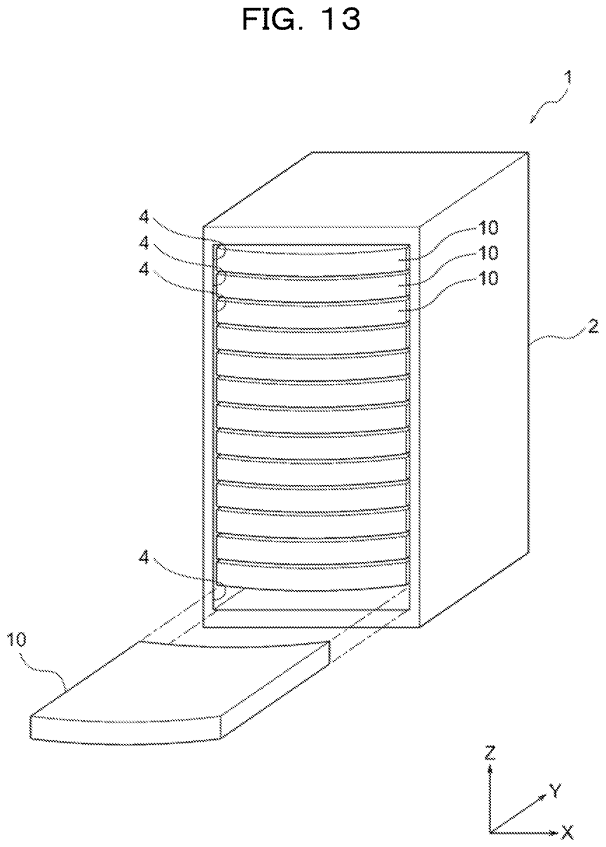

Here, FIG. 13 illustrates a first example of an information processing device 1 in which a plurality of electronic devices 10 are mounted on a rack 2. In the example illustrated in FIG. 13, the electronic devices 10 are inserted in slots 4 except the slot 4 in a bottom stage, and all the electronic devices 10 inserted in the slots 4 deflect. In the case of the example illustrated in FIG. 13, since there is no space for inserting the electronic device 10 in the slot 4 in the bottom stage, the electronic device 10 is not able to be inserted.

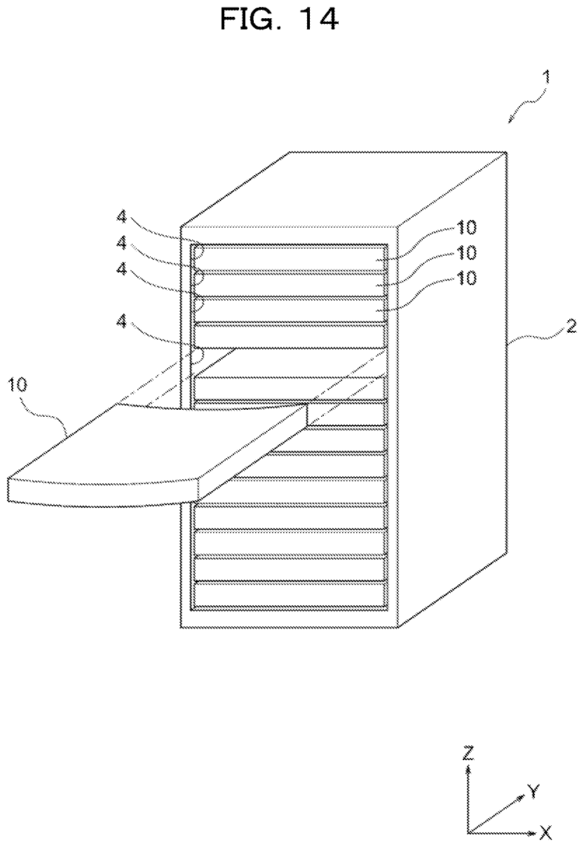

Furthermore, FIG. 14 illustrates a second example of the information processing device 1 in which a plurality of the electronic devices 10 are mounted on the rack 2. In the example illustrated in FIG. 14, the electronic devices 10 are inserted in the slots 4 excluding the slot 4 in a middle stage. In the example illustrated in FIG. 14, the electronic devices 10 inserted in the slots 4 do not deflect but the electronic device 10 to be inserted into one slot 4 in the middle stage deflects. In the case of the example illustrated in FIG. 14, since there is no space for inserting the electronic device 10 in one slot 4 in the middle stage, the electronic device 10 is not able to be inserted.

Therefore, to secure a space in which the electronic device 10 can be inserted in the slot 4, it is conceivable to expand the slot 4. However, this case has a problem that the rack 2 becomes large. Therefore, to avoid an increase in size of the rack 2, it is required to suppress the deflection of the bottom plate 18 of the housing 12. Here, the following techniques are conceivable as techniques for suppressing the deflection of the bottom plate 18 of the housing 12.

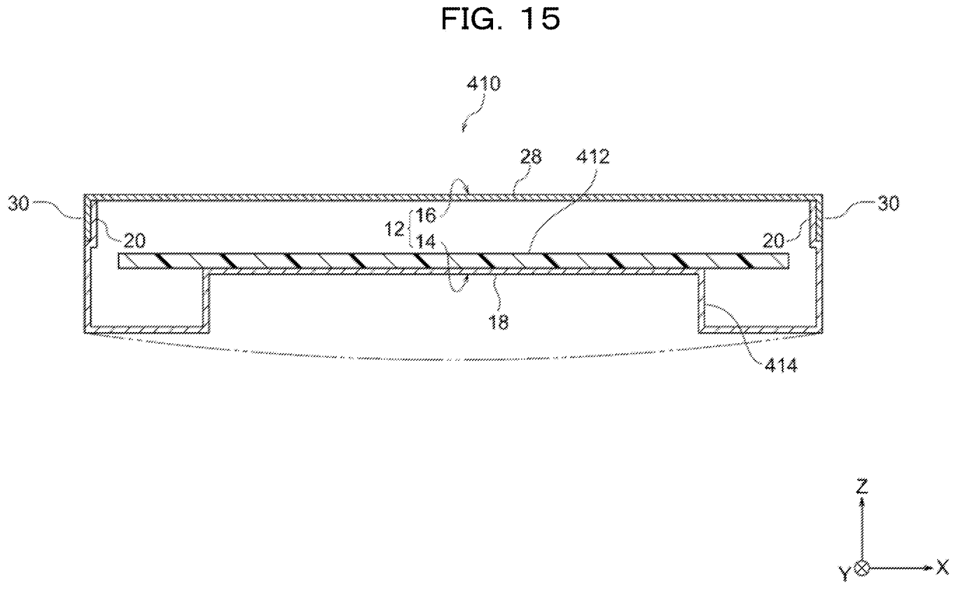

FIG. 15 illustrates an electronic device 410 according to a first comparative example. In FIG. 15, only a substrate 412 of the internal unit is illustrated inside the housing 12 as an example. In the electronic device 410 according to the first comparative example, a drawn portion 414 is formed in the bottom plate 18 by drawing in order to suppress the deflection of the bottom plate 18. However, due to an increase in weight of the internal unit with the recent high-density mounting, it is difficult to suppress the deflection of the bottom plate 18 only by improving the rigidity of the bottom plate 18 by forming the drawn portion 414 in the bottom plate 18. Furthermore, since the drawn portion 414 is formed in the bottom plate 18, the mounting efficiency inside the housing 12 deteriorates as compared with a case where the drawn portion 414 is not provided.

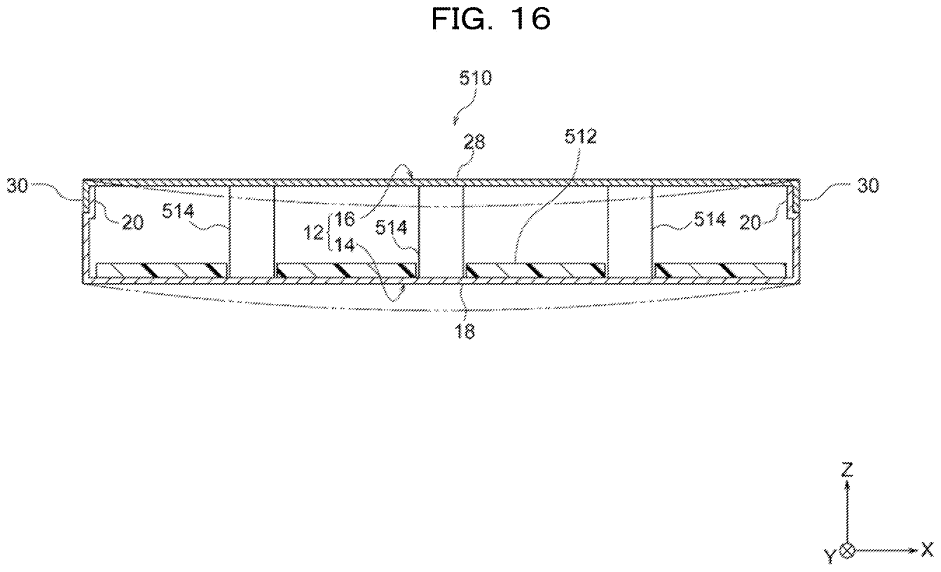

In FIG. 16, an electronic device 510 according to a second comparative example is illustrated. In FIG. 16, only a substrate 512 of the internal unit is illustrated inside the housing 12 as an example. In the electronic device 510 according to the second comparative example, the top plate 28 of the upper housing 16 and the bottom plate 18 of the lower housing 14 are connected by a plurality of pillar members 514 in order to suppress the deflection of the bottom plate 18. However, in a structure in which the top plate 28 of the upper housing 16 and the bottom plate 18 of the lower housing 14 are connected by the plurality of pillar members 514, there is a possibility that the lower housing 14 and the upper housing 16 both deflect. Furthermore, since the plurality of pillar members 514 are arranged inside the housing 12, the substrate 512 needs to be formed in a shape avoiding the plurality of pillar members 514, or the substrate 512 needs to be provided with holes into which the plurality of pillar members 514 are inserted. Therefore, the mounting efficiency of the substrate 512 deteriorates, and eventually the mounting efficiency inside the housing 12 deteriorates.

Therefore, it is required not only to suppress the deflection of the bottom plate 18, but also to suppress the deflection of the bottom plate 18 while ensuring the mounting efficiency inside the housing 12.

Therefore, as illustrated in FIG. 6, the electronic device 18 according to the first embodiment includes the conversion mechanism 40. The conversion mechanism 40 has the first link 46 coupled to the standing wall portion 20 and the second link 48 coupled to the bottom plate 18. Then, as described above, the conversion mechanism 40 converts the tensile force F1 acting on the first link 46 toward the standing wall portion 20 side into the pulling force F2 acting upward on the bottom plate 18 from the second link 48. Therefore, since the pulling force F2 can be applied to the bottom plate 18 by using the standing wall portion 20 having the highest rigidity in the housing 12, the deflection of the bottom plate 18 can be suppressed.

For example, in a case where the deflection occurs in the bottom plate 18 in a state before the pulling force F2 is applied to the bottom plate 18, the deflection of the bottom plate 18 can be removed by applying the pulling force F2 to the bottom plate 18. Furthermore, in the state after the pulling force F2 has been applied to the bottom plate 18, occurrence of the deflection in the bottom plate 18 can be suppressed even if a load is applied to the bottom plate 18 by the internal unit.

Furthermore, since the conversion mechanism 40 has the configuration to pull up the bottom plate 18 by using the standing wall portion 20 having the highest rigidity in the housing 12, as described above, the conversion mechanism 40 can be downsized. Thereby, the mounting efficiency inside the housing 12 can be ensured.

Furthermore, the conversion mechanism 40 includes the link mechanism 42 having the first link 46 and the second link 48. Therefore, the tensile force F1 acting on the first link 46 toward the standing wall portion 20 side can be converted into the pulling force F2 acting upward on the bottom plate 18 from the second link 48 with a simpler configuration than, for example, an electrical configuration using an actuator or the like.

Furthermore, the upper housing 16 has the hanging portion 30 hanging down from the top plate 28. The hanging portion 30 is overlaid on the upper portion of the standing wall portion 20 from the outside of the standing wall portion 20, and is fixed to the standing wall portion 20 by, for example, screwing. Then, by fixing the hanging portion 30 to the standing wall portion 20, the standing wall portion 20 is connected to the upper housing 16. Therefore, in the state where the standing wall portion 20 is connected to the upper housing 16, the rigidity of the standing wall portion 20 can be increased as compared with a state where the standing wall portion 20 is not connected to the upper housing 16.

Furthermore, the electronic device 10 includes the pair of conversion mechanisms 40 corresponding to the pair of standing wall portions 20. Therefore, since the bottom plate 18 can be pulled up using the pair of standing wall portions 20 by the pair of conversion mechanisms 40, the effect of suppressing the deflection of the bottom plate 18 can be enhanced as compared with a case of using only the conversion mechanism 40 on one side, for example.

Furthermore, the first link 46 and the second link 48 are provided inside the housing 12, and the first link 46 is located on the standing, all portion 20 side with respect to the second link 48. Therefore, the first link 46 can be supported by the standing wall portion 20 at a position closer to the standing wall portion 20 than the second link 48. Furthermore, the pulling force F2 can be applied to the bottom plate 18 by the second link 48 arranged at a position closer to the central portion of the bottom plate 18 than the first link 46. Thereby, for example, the tensile force F1 can be more efficiently transmitted to the bottom plate 18 as the pulling force F2 than a case of applying the pulling force F2 to the bottom plate 18 by the second link 48 arranged at a position farther from the central portion of the bottom plate 18 than the first link 46.

Furthermore, the conversion mechanism 40 includes the lock mechanism 44 that can take the unlocked state and the locked state. The unlocked state is a state in which the movement of the first link 46 is allowed to the standing wall portion 20, and the locked state is a state in which the first link 46 is fixed to the standing wall portion 20 in the state where the first link 46 is pulled toward the standing wall portion 20 side. Therefore, for example, by enabling the lock mechanism 44 to be switched from the unlocked state to the locked state, the first link 46 can be pulled toward the standing wall portion 20 side. Thereby, the tensile force F1 acting on the first link 46 toward the standing wall portion 20 side can be converted into the pulling force F2 acting upward on the bottom plate 18 from the second link 48.

Next, a modification of the first embodiment will be described.

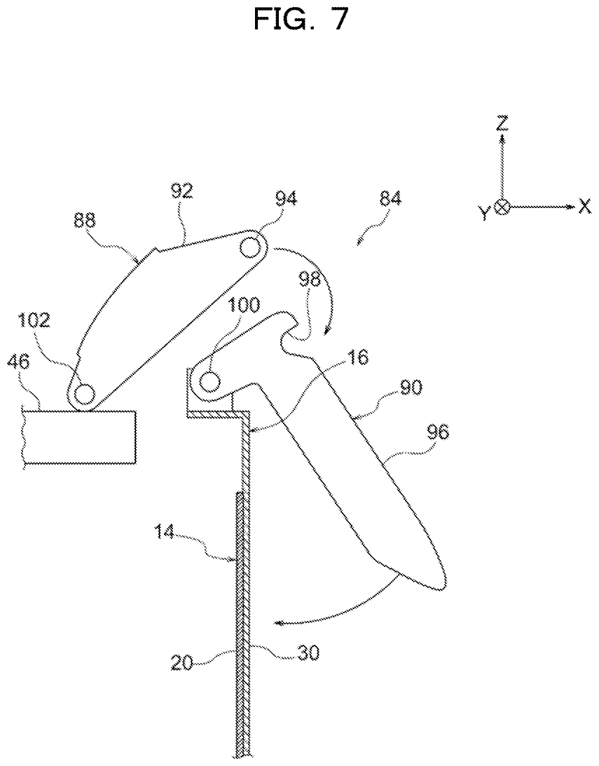

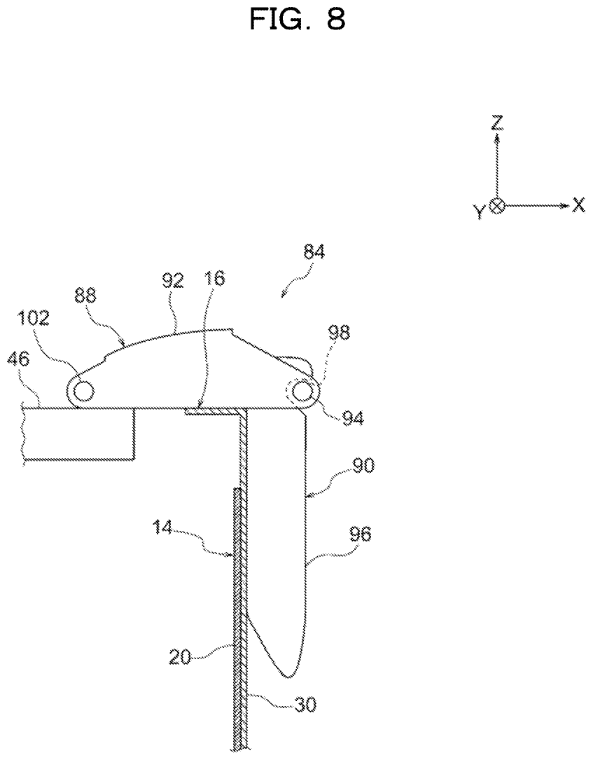

FIGS. 7 and 8 illustrate a lock mechanism 84 according to the modification. The lock mechanism 84 may be used in place of the above-described lock mechanism 44 (FIGS. 4 and 5). The lock mechanism 84 has a locking member 88 and a lever member 90. The locking member 88 is an example of the “first member”, and the lever member 90 is an example of the “second member”. The locking member 88 is provided on the upper surface of the first link 46. The locking member 88 has a main body portion 92 and a locking portion 94. One end of the main body portion 92 is rotatably supported on the upper surface of the first link 46 via a coupling shaft 102. The locking portion 94 is formed in a rod shape and is provided at the other end of the main body portion 92.

The lever member 90 has a lever portion 96 and a locked portion 98. The lever portion 96 is rotatably supported by a corner portion on the hanging portion 30 side of the upper housing 16 via a coupling shaft 100. The lever portion 96 is fixed to the standing wall portion 20 via the upper housing 16 in the state where the upper housing 16 is assembled to the lower housing 14. The lever portion 96 rotates upward when a force is applied to an upper side by an operator, and rotates downward when a force is applied to a lower side by the operator. The locked portion 98 is formed in a groove shape.

The lock mechanism 84 may take an unlocked state and a locked state. FIG. 7 illustrates the unlocked state of the lock mechanism 84, and FIG. 8 illustrates the locked state of the lock mechanism 84.

The unlocked state is a state in which the locking portion 94 is separated from the locked portion 98, and the locking member 88 and the lever member 90 are separated, when the lever portion 96 rotates upward. In the unlocked state, the locking member 88 and the lever member 90 are separated, so that the first link 46 is allowed to move with respect to the standing wall portion 20.

In the locked state, the locking member 88 and the lever member 90 are in the coupled state when the lever portion 96 rotates downward in the state where the locking portion 94 is locked with the locked portion 98 (for example, in a hooked state). A spring (not illustrated) is provided between the lever portion 96 and the coupling shaft 100, and the lever portion 96 is held in a state of being rotated downward by an urging force of the spring in the state where the lever portion 96 is rotated downward. In the locked state, the first link 46 is fixed to the standing wall portion 20 in a state where the first link 46 is pulled toward the standing wall portion 20 side.

Even in the case where the lock mechanism 84 having such a configuration is used, for example, the first link 46 can be pulled toward the standing wall portion 20 side by enabling the lock mechanism 84 to be switched from the unlocked state to the locked state. Thereby, the tensile force F1 (see FIG. 6) acting on the first link 46 toward the standing wall portion 20 side can be converted into the pulling force F2 (see FIG. 6) acting upward on the bottom plate 18 from the second link 48.

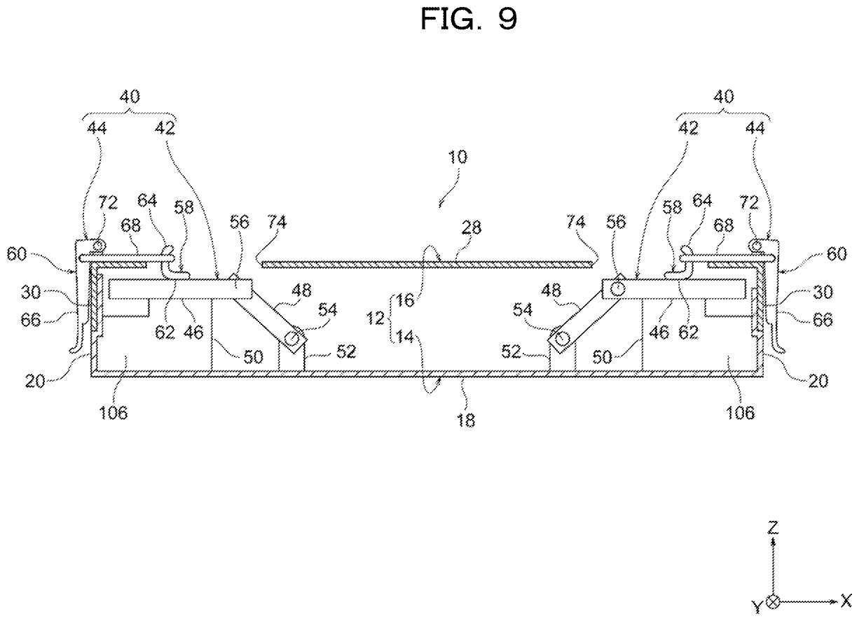

In FIG. 9, the electronic device 10 including the lower housing 14 according to the modification is illustrated. A pair of connecting portions 106 are added to the lower housing 14 according to the modification. Each connecting portion 106 is, for example, a rib or the like, and connects the standing wall portion 20 and the support portion 50. The connecting portion 106 may be erected from the bottom plate 18 or may be separated from the bottom plate 18.

When the standing wall portion 20 and the support portion 50 are connected by the connecting portion 106 in this way, the rigidity of the standing wall portion 20 can be increased as compared with a case where the connecting portion 106 is not provided. Thereby, the tensile force F1 (see FIG. 6) acting on the first link 46 toward the standing wall portion 20 side can be efficiently converted into the pulling force F2 (see FIG. 6) acting upward on the bottom plate 18 from the second link 48.

Note that, in the above-described first embodiment, the rigidity of the standing wall portion 20 is ensured by the standing wall portion 20 being connected to the upper housing 16, but the rigidity of the standing wall portion 20 may be ensured by a structure other than the standing wall portion 20 being connected to the upper housing 16.

Furthermore, in the above-described first embodiment, the conversion mechanism 40 includes the link mechanism 42 having the first link 46 and the second link 48. However, the conversion mechanism 40 may have a mechanism having the first coupling portion coupled to the standing wall portion 20 and the second coupling portion coupling the first coupling portion and the bottom plate 18, other than the link mechanism 42. Then, the conversion mechanism 40 may be configured to convert the tensile force F1 acting on the first coupling portion toward the standing wall portion 20 side into the pulling force F2 acting upward on the bottom plate 18 from the second coupling portion by a mechanism other than the link mechanism 42.

For example, as the mechanism other than the link mechanism 42, a wire mechanism having the first coupling portion coupled to the standing wall portion 20 and the second coupling portion coupling the first coupling portion and the bottom plate 18 may be adopted. Then, the conversion mechanism 40 may convert the tensile force F1 acting on the first coupling portion toward the standing wall portion 20 side into the pulling force F2 acting upward on the bottom plate 18 from the second coupling portion by the wire mechanism.

Furthermore, the conversion mechanism 40 may be configured to be able to adjust an amount of movement of the first link 46 toward the standing wall portion 20 side, and thus the amount of movement to the upper side of the bottom plate 18.

Furthermore, in the above-described first embodiment, the electronic device 10 includes the conversion mechanisms 40 on both sides, but the electronic device 10 may have only the conversion mechanism 40 on one side. Furthermore, the conversion mechanism 40 may be arranged corresponding to a position where the deflection of the bottom plate 18 becomes large.

Furthermore, as an example, the electronic device 10 is an electronic device mounted on the rack 2, but may not be an electronic device mounted on the rack 2.

Furthermore, as an example, the standing wall portion 20 is a side wall portion located on the side surface of the housing 12, but may be a front wall portion located on a front surface of the housing 12 or a rear wall portion located on a back surface of the housing 12.

Furthermore, the above-described plurality of modifications may be carried out in combination as appropriate.

### Second Embodiment

Next, a second embodiment of the technique disclosed in the present application will be described.

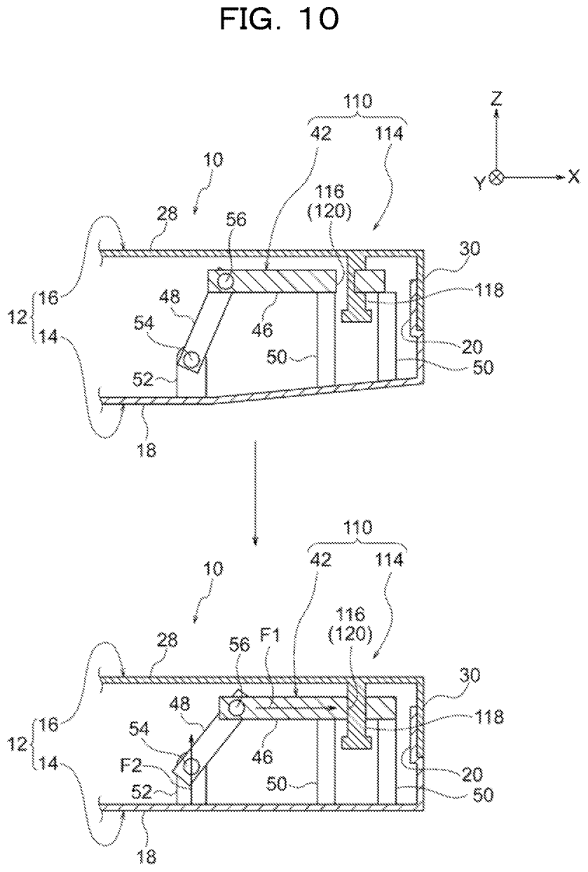

FIG. 10 illustrates an electronic device 10 according to the second embodiment. In the second embodiment, the configuration of the electronic device 10 is changed as follows with respect to the first embodiment. For example, an upper housing 16 is supported with respect to a lower housing 14 so as to be movable (slidable as an example) in a Y direction. In the upper figure of FIG. 10, a state before the upper housing 16 moves to a regular position with respect to the lower housing 14 is illustrated, and in the lower figure of FIG. 10, a state after the upper housing 16 has moved to the regular position with respect to the lower housing 14 is illustrated.

A pair of support portions 50 are erected on a bottom plate 18, and a first link 46 is supported by an upper surface of the pair of support portions 50 so as to be movable in an X direction. The X direction is a direction of approaching or separating with respect to a standing wall portion 20 in plan view of a housing 12, and is an example of a “first direction”. The Y direction is a direction of intersecting with the X direction in plan view, and is an example of a “second direction”. The plan view of the housing 12 corresponds to viewing the housing 12 along a Z direction.

The electronic device 10 according to the second embodiment includes a conversion mechanism 110 instead of the conversion mechanism 40 (see FIG. 6) in the first embodiment. The conversion mechanism 110 includes a link mechanism 42 and an interlocking mechanism 114. The link mechanism 42 has a similar configuration to that of the first embodiment except that a groove 116 to be described below is formed in the first link 46. The interlocking mechanism 114 has the groove 116 and a pin 118. The pin 118 is provided on a top plate 28. The pin 118 extends downward from the top plate 28.

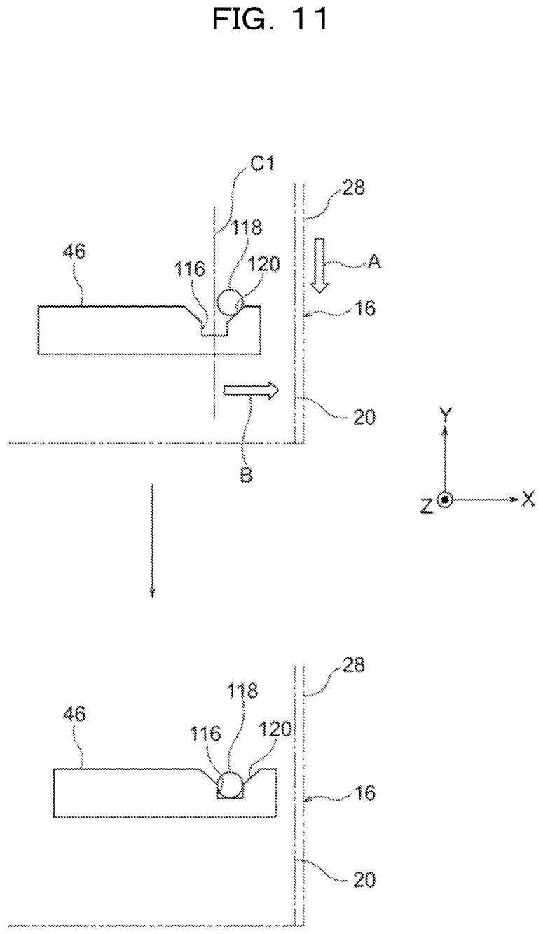

In FIG. 11, a positional relationship between the pin 118 provided on the top plate 28 and the groove 116 formed in the first link 46 is illustrated. The groove 116 has a tapered surface 120. The tapered surface 120 is formed in a tapered shape having a width narrowing toward a side where the upper housing 16 moves to the regular position with respect to the lower housing 14 (for example, the arrow A side). The pin 118 is located on the standing wall portion 20 side (for example, the arrow B side) with respect to a center line C1 of the groove 116 in the state before the upper housing 16 moves to the regular position with respect to the lower housing 14.

When the upper housing 16 moves along the Y direction toward the regular position with respect to the lower housing 14 (for example, moves toward the arrow A side), the pin 118 slides with the tapered surface 120 as the upper housing 16 moves. When the pin 118 slides with the tapered surface 120, the first link 46 is pulled toward the standing wall portion 20 side (for example, the arrow B side) along the X direction. For example, the interlocking mechanism 114 has a function to pull the first link 46 toward the standing wall portion 20 side along the X direction as the upper housing 16 moves in the Y direction. The interlocking mechanism 114 is an example of a “first interlocking mechanism”, the tapered surface 120 is an example of a “first tapered surface”, and the pin 118 is an example of a “first pin”.

Next, a method of using the conversion mechanism 110 according to the second embodiment will be described.

In the method of using the conversion mechanism 110 according to the second embodiment, first, the upper housing 16 is assembled to a temporary position of the lower housing 14. The temporary position is a position before the upper housing 16 is moved to the regular position with respect to the lower housing 14. At this time, the pin 118 is arranged near an entrance of the tapered surface 120. Then, a force is applied to the upper housing 16, so that the upper housing 16 moves to the regular position with respect to the lower housing 14 along the Y direction (for example, moves to the arrow A side). When the upper housing 16 has moved along the Y direction toward the regular position with respect to the lower housing 14, the pin 118 slides with the tapered surface 120 as the upper housing 16 moves. When the pin 118 slides with the tapered surface 120, the first link 46 is pulled toward the standing wall portion 20 side (for example, the arrow B side) along the X direction.

When the first link 46 is pulled toward the standing wall portion 20 side, a tensile force F1 acts on the first link 46 toward the standing wall portion 20 side. When the tensile force F1 acts on the first link 46 toward the standing wall portion 20 side, the tensile force F1 is transmitted to a second link 48, and an upward pulling force F2 acts on the bottom plate 18 from the second link 48.

Then, the tensile force F1 acting on the first link 46 toward the standing wall portion 20 side is converted by the conversion mechanism 110 into the pulling force F2 acting upward on the bottom plate 18 from the second link 48, whereby the deflection of the bottom plate 18 is suppressed. The method of using the conversion mechanism 110 is an example of the “deflection suppressing method”.

Next, operation and effect of the second embodiment will be described.

The electronic device 10 according to the second embodiment includes the conversion mechanism 110. The conversion mechanism 110 has the first link 46 coupled to the standing wall portion 20 and the second link 48 coupled to the bottom plate 18. Then, as described above, the conversion mechanism 110 converts the tensile force F1 acting on the first link 46 toward the standing wall portion 20 side into the pulling force F2 acting upward on the bottom plate 18 from the second link 48. Therefore, since the pulling force F2 can be applied to the bottom plate 18 by using the standing wall portion 20 having the highest rigidity in the housing 12, the deflection of the bottom plate 18 can be suppressed.

For example, in a case where the deflection occurs in the bottom plate 18 in a state before the pulling force F2 is applied to the bottom plate 18, the deflection of the bottom plate 18 can be removed by applying the pulling force F2 to the bottom plate 18. Furthermore, in the state after the pulling force F2 has been applied to the bottom plate 18, occurrence of the deflection in the bottom plate 18 can be suppressed even if a load is applied to the bottom plate 18 by an internal unit.

Furthermore, since the conversion mechanism 110 has the configuration to pull up the bottom plate 18 by using the standing wall portion 20 having the highest rigidity in the housing 12, as described above, the conversion mechanism 110 can be downsized. Thereby, the mounting efficiency inside the housing 12 can be ensured.

Furthermore, the conversion mechanism 110 includes the link mechanism 42 having the first link 46 and the second link 48. Therefore, the tensile force F1 acting on the first link 46 toward the standing wall portion 20 side can be converted into the pulling force F2 acting upward on the bottom plate 18 from the second link 48 with a simpler configuration than, for example, an electrical configuration using an actuator or the like.

Furthermore, the electronic device 10 includes the pair of conversion mechanisms 110 corresponding to the pair of standing wall portions 20. Therefore, since the bottom plate 18 can be pulled up using the pair of standing wall portions 20 by the pair of conversion mechanisms 110, the effect of suppressing the deflection of the bottom plate 18 can be enhanced as compared with a case of using only the conversion mechanism 110 on one side, for example.

Furthermore, the conversion mechanism 110 includes the interlocking mechanism 114. The interlocking mechanism 114 is a mechanism to pull the first link 46 toward the standing wall portion 20 side along the X direction as the upper housing 16 moves in the Y direction. Therefore, the first link 46 can be pulled toward the standing wall portion 20 side in conjunction with the movement of the upper housing 16 in the Y direction. Thereby, the tensile force F1 acting on the first link 46 toward the standing wall portion 20 side can be converted into the pulling force F2 acting upward on the bottom plate 18 from the second link 48.

Furthermore, the interlocking mechanism 114 has a mechanical configuration having the tapered surface 120 formed on the first link 46 and the pin 118 provided on the upper housing 16. Therefore, for example, the configuration of the interlocking mechanism 114 can be simplified as compared with a case where the interlocking mechanism 114 has an electrical configuration using an actuator or the like.

Next, a modification of the second embodiment will be described.

In the above-described second embodiment, the interlocking mechanism 114 has the tapered surface 120 formed on the first link 46 and the pin 118 provided on the upper housing 16. However, the interlocking mechanism 114 may have a structure other than the tapered surface 120 and the pin 118 as long as the structure has the configuration to pull the first link 46 toward the standing wall portion 20 side along the X direction with the movement of the upper housing 16 in the Y direction.

Furthermore, in the above-described second embodiment, the upper housing 16 is supported with respect to the lower housing 14 so as to be movable in the Y direction. However, for example, in a case where the electronic device 10 has only the conversion mechanism 110 on one side, the upper housing 16 may be supported with respect to the lower housing 14 so as to be movable in the X direction. Furthermore, in this case, the interlocking mechanism 114 may be configured to pull the first link 46 toward the standing wall portion 20 side along the X direction as the upper housing 16 moves in the X direction.

Furthermore, the modification applicable to the second embodiment among the modifications described in the above-described first embodiment may be applied to the second embodiment.

### Third Embodiment

Next, a third embodiment of the technique disclosed in the present application will be described.

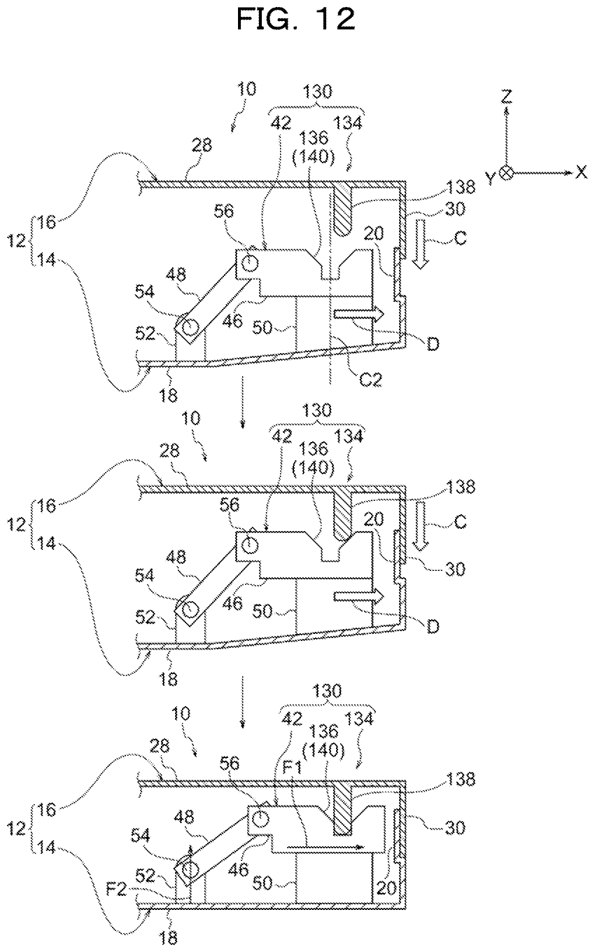

In FIG. 12, a state where an upper housing 16 is assembled to a lower housing 14 in stages in an electronic device 10 according to a third embodiment is illustrated. In the electronic device 10 according to the third embodiment, the upper housing 16 is assembled to the lower housing 14 along a Z direction as in the first embodiment.

Furthermore, similarly to the first embodiment, a support portion 50 is erected on a bottom plate 18, and a first link 46 is supported by an upper surface of the support portion 50 so as to be movable in an X direction. The X direction is a direction of approaching or separating with respect to a standing wall portion 20 in plan view of a housing 12, and is an example of a “third direction”. The Z direction is an up-down direction of the housing 12, and is an example of a “fourth direction”. The plan view of the housing 12 corresponds to viewing the housing 12 along the Z direction.

The electronic device 10 according to the third embodiment includes a conversion mechanism 130 instead of the conversion mechanism 40 (see FIG. 6) in the first embodiment. The conversion mechanism 130 includes a link mechanism 42 and an interlocking mechanism 134. The link mechanism 42 has a similar configuration to that of the first embodiment except that a groove 136 to be described below is formed in the first link 46. The interlocking mechanism 134 has the groove 136 and a pin 138. The pin 138 is provided on a top plate 28. The pin 138 extends downward from the top plate 28.

The groove 136 has a tapered surface 140. The tapered surface 140 is formed in a tapered shape having a width narrowing toward a side where the upper housing 16 is assembled to the lower housing 14 (for example, the arrow C side). The pin 138 is located on the standing wall portion 20 side (for example, the arrow D side) with respect to a center line C2 of the groove 136 in a state before the upper housing 16 is assembled to the lower housing 14.

When the upper housing 16 moves along the Z direction toward the side assembled to the lower housing 14 (for example, moves toward the arrow C side), the pin 138 slides with the tapered surface 140 as the upper housing 16 moves. When the pin 138 slides with the tapered surface 140, the first link 46 is pulled toward the standing wall portion 20 side (for example, the arrow D side) along the X direction. For example, the interlocking mechanism 134 has a function to pull the first link 46 toward the standing wall portion 20 side along the X direction as the upper housing 16 moves in the Z direction. The interlocking mechanism 134 is an example of a “second interlocking mechanism”, the tapered surface 140 is an example of a “second tapered surface”, and the pin 138 is an example of a “second pin”.

Next, a method of using the conversion mechanism 130 according to the third embodiment will be described.

In the method of using the conversion mechanism 130 according to the third embodiment, the upper housing 16 is assembled to the lower housing 14 along the Z direction. When the upper housing 16 moves along the Z direction toward the side assembled to the lower housing 14 (for example, toward the arrow C side), the pin 138 slides with the tapered surface 140 as the upper housing 16 moves. When the pin 138 slides with the tapered surface 140, the first link 46 is pulled toward the standing wall portion 20 side (for example, the arrow D side) along the X direction.

When the first link 46 is pulled toward the standing wall portion 20 side, a tensile force F1 acts on the first link 46 toward the standing wall portion 20 side. When the tensile force F1 acts on the first link 46 toward the standing wall portion 20 side, the tensile force F1 is transmitted to a second link 48, and the upward pulling force F2 acts on the bottom plate 18 from the second link 48.

Then, the tensile force F1 acting on the first link 46 toward the standing wall portion 20 side is converted by the conversion mechanism 130 into the pulling force F2 acting upward on the bottom plate 18 from the second link 48, whereby the deflection of the bottom plate 18 is suppressed. The method of using the conversion mechanism 130 is an example of the “deflection suppressing method”.

Next, operation and effect of the third embodiment will be described.

The electronic device 10 according to the third embodiment includes the conversion mechanism 130. The conversion mechanism 130 has the first link 46 coupled to the standing wall portion 20 and the second link 48 coupled to the bottom plate 18. Then, as described above, the conversion mechanism 130 converts the tensile force F1 acting on the first link 46 toward the standing wall portion 20 side into the pulling force F2 acting upward on the bottom plate 18 from the second link 48. Therefore, since the pulling force F2 can be applied to the bottom plate 18 by using the standing wall portion 20 having the highest rigidity in the housing 12, the deflection of the bottom plate 18 can be suppressed.

For example, in a case where the deflection occurs in the bottom plate 18 in a state before the pulling force F2 is applied to the bottom plate 18, the deflection of the bottom plate 18 can be removed by applying the pulling force F2 to the bottom plate 18. Furthermore, in the state after the pulling force F2 has been applied to the bottom plate 18, occurrence of the deflection in the bottom plate 18 can be suppressed even if a load is applied to the bottom plate 18 by an internal unit.

Furthermore, since the conversion mechanism 130 has the configuration to pull up the bottom plate 18 by using the standing wall portion 20 having the highest rigidity in the housing 12, as described above, the conversion mechanism 130 can be downsized. Thereby, the mounting efficiency inside the housing 12 can be ensured.

Furthermore, the conversion mechanism 130 includes the link mechanism 42 having the first link 46 and the second link 48. Therefore, the tensile force F1 acting on the first link 46 toward the standing wall portion 20 side can be converted into the pulling force F2 acting upward on the bottom plate 18 from the second link 48 with a simpler configuration than, for example, an electrical configuration using an actuator or the like.

Furthermore, the electronic device 10 includes the pair of conversion mechanisms 130 corresponding to the pair of standing wall portions 20. Therefore, since the bottom plate 18 can be pulled up using the pair of standing wall portions 20 by the pair of conversion mechanisms 130, the effect of suppressing the deflection of the bottom plate 18 can be enhanced as compared with a case of using only the conversion mechanism 130 on one side, for example.

Furthermore, the conversion mechanism 130 includes an interlocking mechanism 134. The interlocking mechanism 134 is a mechanism to pull the first link 46 toward the standing wall portion 20 side along the X direction as the upper housing 16 moves in the Z direction. Therefore, the first link 46 can be pulled toward the standing wall portion 20 side in conjunction with the movement of the upper housing 16 in the Z direction. Thereby, the tensile force F1 acting on the first link 46 toward the standing wall portion 20 side can be converted into the pulling force F2 acting upward on the bottom plate 18 from the second link 48.

Furthermore, the Z direction is an assembly direction of the upper housing 16 with respect to the lower housing 14. Therefore, to operate the interlocking mechanism 134, the upper housing 16 is simply assembled to the lower housing 14 along the Z direction. Therefore, a special operation for operating the interlocking mechanism 134 can be omitted.

Furthermore, since the upper housing 16 does not need to be moved in the Y direction in order to operate the interlocking mechanism 134 as in the second embodiment, the degree of freedom in designing the housing 12 can be increased as compared with the second embodiment.

Furthermore, the interlocking mechanism 134 has a mechanical configuration having the tapered surface 140 formed on the first link 46 and the pin 138 provided on the upper housing 16. Therefore, for example, the configuration of the interlocking mechanism 134 can be simplified as compared with a case where the interlocking mechanism 134 has an electrical configuration using an actuator or the like.

Next, a modification of the third embodiment will be described.

In the above-described third embodiment, the interlocking mechanism 134 has the tapered surface 140 formed on the first link 46 and the pin 138 provided on the upper housing 16. However, the interlocking mechanism 134 may have a structure other than the tapered surface 140 and the pin 138 as long as the structure has the configuration to pull the first link 46 toward the standing wall portion 20 side along the X direction with the movement of the upper housing 16 in the Z direction.

Furthermore, the modification applicable to the third embodiment among the modifications described in the above-described first embodiment may be applied to the third embodiment.

While the first to third embodiments of the technology disclosed in the present application have been described thus far, the technology disclosed in the present application is not limited to the above-described embodiments, and it will be understood that various modifications may be made and implemented within the spirit and scope of the technology in addition to the above-described embodiments.

All examples and conditional language provided herein are intended for the pedagogical purposes of aiding the reader in understanding the invention and the concepts contributed by the inventor to further the ait, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic device comprising:
a housing that includes a bottom plate and a standing wall erected over the bottom plate; and
a conversion mechanism that includes a first coupler coupled to the standing wall and a second coupler by which the first coupler is coupled to the bottom plate, and configured to convert a tensile force to act on the first coupler toward a side of the standing wall into a pulling force to act on the bottom plate from the second coupler.

2. The electronic device according to claim 1, wherein
the conversion mechanism includes a link mechanism that includes a first link as the first coupler and a second link as the second coupler.

3. The electronic device according to claim 1, wherein
the housing includes
a lower housing that includes the bottom plate, and
an upper housing that includes a top plate, and
the standing wall is coupled to the upper housing.

4. The electronic device according to claim 1, wherein
the standing wall includes
a first standing wall erected over a first edge of the bottom plate, and
a second standing wall erected over a second edge on an opposite side of the first edge of the bottom plate, and
the conversion mechanism includes
a first conversion mechanism by which the first standing wall is coupled to the bottom plate, and
a second conversion mechanism by which the second standing wall is coupled to the bottom plate.

5. The electronic device according to claim 1, wherein
the housing includes
a supporter that is erected over the bottom plate and supports the first coupler, and
a connector by which the standing wall is coupled to the supporter.

6. The electronic device according to claim 1, wherein
the first coupler and the second coupler are provided inside the housing, and
the first coupler is located over the side of the standing wall with respect to the second coupler.

7. The electronic device according to claim 1, wherein
the conversion mechanism includes a lock mechanism able to take an unlocked state that allows the first coupler to move with respect to the standing wall, and a locked state in which the first coupler is fixed to the standing wall in a state where the first coupler is pulled toward the side of the standing wall.

8. The electronic device according to claim 7, wherein
the lock mechanism includes
a first member fixed to the first coupler, and
a second member fixed to the standing wall,
the unlocked state is a state in which the first member and the second member are separated, and
the locked state is a state in which the first member is coupled to the second member.

9. The electronic device according to claim 1, wherein
the housing includes
a lower housing that includes the bottom plate, and
an upper housing that includes a top plate,
the first coupler is supported with respect to the lower housing so as to be movable in a first direction that is a direction of approaching or separating with respect to the standing wall in plan view of the housing,
the upper housing is supported with respect to the lower housing so as to be movable in a second direction that intersects with the first direction in the plan view, and
the conversion mechanism includes a first interlocking mechanism configured to pull the first coupler toward the side of the standing wall along the first direction as the upper housing moves in the second direction.

10. The electronic device according to claim 9, wherein
the first interlocking mechanism includes
a first tapered surface formed over the first coupler, and
a first pin provided over the upper housing and configured to slide with the first tapered surface as the upper housing moves in the second direction.

11. The electronic device according to claim 1, wherein
the housing includes
a lower housing that includes the bottom plate, and
an upper housing that includes a top plate,
the first coupler is supported with respect to the lower housing so as to be movable in a third direction that is a direction of approaching or separating with respect to the standing wall in plan view of the housing,
the upper housing is supported with respect to the lower housing so as to be movable in a fourth direction that is an up-down direction of the housing, and
the conversion mechanism includes a second interlocking mechanism configured to pull the first coupler toward the side of the standing wall along the third direction as the upper housing moves in the fourth direction.

12. The electronic device according to claim 11, wherein
the second interlocking mechanism includes
a second tapered surface formed over the first coupler, and
a second pin provided over the upper housing and configured to slide with the second tapered surface as the upper housing moves in the fourth direction.

13. A deflection suppressing method of an electronic device, the deflection suppressing method comprising:
wherein the electronic device includes
a housing that includes a bottom plate and a standing wall erected over the bottom plate, and
a conversion mechanism that includes a first coupler coupled to the standing wall and a second coupler coupled to the bottom plate,
suppressing deflection of the bottom plate by converting a tensile force to act on the first coupler toward a side of the standing wall into a pulling force to act on the bottom plate from the second coupler, by using the conversion mechanism.
